(19) United States
(12) Patent Application Publication
(10) Pub. No.: US 2025/0140631 A1
(43) Pub. Date: May 1, 2025

(54) Component holder with a temperature-control function

(71) Applicant: BESI Switzerland AG, Steinhausen (CH)

(72) Inventor: Uwe BAYER, Kramsach (AT)

(21) Appl. No.: 18/927,693

(22) Filed: Oct. 25, 2024

(30) Foreign Application Priority Data
Oct. 25, 2023 (DE) 102023129487.3

(51) Int. Cl. H01L 23/34; H01C 7/02; H01L 23/40

(52) U.S. Cl. CPC H01L 23/345; H01C 7/021; H01L 23/40

(57) ABSTRACT

A component holder (1) for processing a component, includes a support (100), a component holding tool (300) with a component contact surface (350) and a temperature-control apparatus (200) for thermally shielding one or more areas of the component contact surface (350) of the component holding tool (300) from the support (1) relative to a predefined process temperature.

### CROSS REFERENCE TO RELATED APPLICATION

This application claims the priority of German patent application DE 102023129487.3 filed on Oct. 25, 2023; the application is incorporated by reference herein in its entirety.

### TECHNICAL FIELD

The invention relates to a component holder with a temperature-control function according to the features of claim 1 and its use according to the features of claim 22.

### STATE OF THE ART

Component holders for the installation of components in a wide variety of forms for a wide variety of applications are well-known from the state of the art. Component holders are usually used in the production of electrical components or assemblies in the case of the installation of semiconductor chips on substrates. The use of component holders in the case of thermal assembly processes, such as soldering or bonding, is problematic. Due to the two different masses of a component holder and a component to be held by the component holder, strong temperature gradients occur, which may have a negative influence on the assembly processes.

It is also well-known from the state of the art that electrical components made of materials with a positive temperature coefficient, so-called PTC elements, are often used in protective circuits, in particular as fuses. Their electrical resistance increases if the temperature of the environment increases. Due to this effect, they are often used as fuse elements to limit the flow of current, as the PTC element heats up in the case of increasing current. As a result of the heating, the electrical resistance of the element increases and limits the current flow. In the case of an unexpectedly high or uncontrolled increase in current (or heat) in a very short time, the heat development causes the PTC element to melt and interrupts the current flow by destroying the PTC element in this way.

Various solutions for component holders, including their advantages and disadvantages, are also presented and discussed in detail in published patent documents such as DD 270180 A10, JP 567513 82, U.S. Pat. No. 1,163,597 82, US 2003/0075537 A1, US 2005/0258160 A1 and US 2014/0184312 A1.

### SUMMARY

It is an object of the invention to provide a component holder for holding components, such as electrical components or semiconductor chips, for component assembly, whose temperature behaviour can be adapted and maintained at the direct process ambient temperature of a component, even at high process cycles, despite its relatively large mass.

The problem is solved by the technical apparatus according to independent claim 1 and its use according to claim 22. Technically advantageous embodiments are set out in the dependent claims, the description and the drawings.

### DETAILED DESCRIPTION

According to one aspect of the invention, a component holder for processing a component comprises as elements: a support, a component holding tool having a component contact surface and a temperature-control apparatus for thermally shielding one or more areas of the component contact surface of the component holding tool relative to the support, relative to a predefined process temperature.

According to another aspect of the invention, a component holder for processing a component comprises as elements: a support, a component holding tool with a component contact surface and a temperature-control apparatus, wherein the temperature-control apparatus is arranged between the support and the component holding tool in such a way that one or more areas of the component contact surface of the component holding tool can be temperature-controlled relative to the support, relative to a predefined process temperature, in such a way that, during processing of the component, one or more areas of the component contact surface of the component holding tool are thermally shielded or can be shielded from the support.

In the case of both of these aspects, thermal shielding is accomplished in particular by compensating a temperature difference that occurs between the elements.

In the case of both of these aspects, the component holder and/or at least one of its elements preferably has a relatively large mass in order to be able to counteract process-related vibrations by means of inertia. The large mass is associated with a sluggish heating and/or cooling behaviour, with which supplied and/or dissipated heat energy can only release its effect with a time delay in the form of heat radiation or cold radiation to one or more areas of the component contact surface. However, this disadvantage can be optimised by using thermally matched materials so that the thermal conductivity is optimal due to the matched thermal conductivity coefficients and thicknesses of the materials along the path of heat flow, so that the heat energy supplied and/or dissipated in at least one way in a very short time counteracts the inertia.

In both aspects, thermal energy (temperature) is supplyable to and/or dissipatable from the component holder and/or at least one of its elements from at least one heat source and/or heat sink. Preferably, one or more heat source(s) and/or heat sink(s) are embedded in the component holder and/or in at least one of its elements. Preferably, in both aspects, heat source(s) and/or heat sink(s) are arranged extending in the spatial volume of the component holder and/or at least one of its elements and/or are arranged extending in a plane of the component holder and/or at least one of its elements.

In the case of both aspects, the spatial volume and/or the plane is preferably divided into temperature zones. This has the advantage that the temperature to be supplied and/or drained can be optimally controlled by predefined temperature values adapted to the process of a component to be processed and target deviations can be continuously reduced by control loops. In particular, external environmental influences can be reduced to a greater extent, which allows for more stable processes.

In embodiments of a component holder, the component holder and/or one or more of its, preferably all, elements, in particular the support, the component holding tool and the temperature-control apparatus, each comprise at least one media line section extending in the spatial volume within a temperature zone.

Preferably, the media line sections are each arranged in such a way that, in the case of a force-fitting and/or form-fitting connection of the support to the temperature-control apparatus and a force-fitting and/or form-fitting connection of the temperature-control apparatus to the component holding tool, a continuous media line is formed from at least two media line sections, through which, in a first manner, at least a portion of the relatively positive and/or negative temperature for temperature-controlling a temperature zone can be supplied to and/or drained from, within a few seconds, at least one temperature zone by means of at least one medium, preferably for the processing of the component. Thereby, in the case of one media line, an alternating supply and/or draining of temperature within a temperature zone through the same media line is just as possible as in the case of two or more media lines.

Technical gases are particularly suitable as a medium, which, in particular when pressurised to high pressure, allow for temperature-control within a few seconds, preferably within a few milliseconds.

In embodiments of a component holder, the component holder and/or one or more, preferably all, of its elements comprise one or more heating elements to provide at least a portion of the relatively positive temperature for temperature-control within a temperature zone in a second manner.

Preferred embodiments of a component holder comprising heat source(s) and/or heat sink(s) arranged extending in the spatial volume of the component holder and/or at least one of its elements and/or arranged extending in a plane of the component holder and/or at least one of its elements in order to provide at least a portion of the positive or negative temperature for temperature-control in the two ways described above.

In the context of the disclosure, temperature that can be supplied and/or drained within a very short time is used to temperature-control a spatial temperature zone arranged in the volume or in the plane in order to bring one or more areas of the component contact surface to a certain temperature and to maintain this temperature during the processing of a component. Preferably, the thermal conductivity coefficients of the materials of the individual elements are matched to each other to optimise the overall thermal conductivity.

In embodiments of a component holder with multiple heating elements, at least one heating element may be a PTC thermistor heating element.

In embodiments of a component holder with multiple heating elements, the heating elements may be electrically connected in series to one another, particularly preferably in parallel.

In such embodiments of a component holder with one or more heating elements, the one or more heating elements may be arranged in one or more temperature zones.

The connection in parallel of heating elements, in contrast to a serial circuit, has the advantage that in the event of a temperature difference between two areas of the component contact surface or two temperature zones of the temperature-control apparatus, the electrical resistance of an embedded PTC thermistor heating element increases in the area or temperature zone with the higher temperature. According to the laws of electrical connections in parallel, the same voltage is adjoined to each electrical resistance. However, the electrical current is lower if the electrical resistance in one arm of an electrical circuit is higher. This means that a high electrical resistance in an area or temperature zone due to a higher temperature leads to a low current in this arm and thus to a lower heating power in this area or temperature zone. The temperature then decreases, which also reduces the electrical resistance in this area or temperature zone. The negative feedback loop which is realised in this way allows for a self-adapting control system for temperature-control. The result is a uniform temperature distribution on the component contact surface despite fluctuating or inhomogeneous process temperatures and/or ambient temperatures.

In addition, manufacturing tolerances (or minor defects) in the PTC thermistors are compensated which result in a higher acceptable yield at the processing of the heating device and thus lower production costs.

In addition, there is potential for cost reduction, as the automatically adaptive behaviour of the design can lead to fewer heating devices being required, where otherwise a separate controller and its own thermocouple would be required for each heating device.

In the case of an equally usable serial circuit, an increase in temperature in an area or temperature zone leads to a higher electrical resistance of a PTC thermistor heating element embedded in it in the same scenario described above. According to the laws of electrical series circuits, the same electrical current is present at every electrical resistance. The higher the electrical resistance, the higher the electrical voltage. This means that a high electrical resistance in the area or temperature zone will result in a high voltage in that zone, and thus a higher heating output. The temperature rises in an area or temperature zone. The electrical resistance increases in that area or temperature zone. This is a positive feedback loop and leads to a self-reinforcing system. The result is a hotspot on the heating element.

In embodiments of a component holder, the heating elements of each temperature zone are electrically connected to a respective electrical power supply, wherein each of the electrical power supplies is arranged to provide a predetermined and/or controlled supply of electrical energy to the heating elements of a temperature zone. Preferably, the number of power supplies therefore corresponds to the number of temperature zones, so that each temperature zone has a power supply.

In embodiments of a component holder, preferably at least one of the temperature zones is arranged in an inner central area of the component contact surface, wherein at least one more temperature zone is arranged in one or more outer areas of the component contact surface peripheral to the inner central area.

In the case of embodiments of a component holder, preferably one or more heating elements or one or more PTC thermistor heating elements are manufactured using thin-film technology or, for extremely powerful heating elements, using thick-film technology and are embedded in a temperature-control layer in this way. Thermal expansion usually causes a change in the length/thickness or a deflection of a temperature-control layer.

In addition, the manufacturing of the temperature-control apparatus using thin-film technology or thick-film technology to form a layered composite of multiple temperature-control layers with summable temperature supplies or temperature dissipations of summable temperature in the case of simultaneous or alternating temperature supplies and/or temperature dissipations allows for improved temperature-control for thermal shielding.

By using temperature-compensated materials for temperature-control layers of a temperature-control apparatus for all embodiments of a component holder, preferably alternating pairs of layer material with matched thermal expansion coefficients which compensate each other as a pair of layers, or especially mechanically rigid materials for the temperature-control layers in general, such as ceramics, sintered ceramics, technical glasses, sapphire or semiconductor materials, a thermally induced deformation of the composite layer of a temperature-control apparatus can be reduced in an advantageous manner.

In embodiments of a component holder, preferably the component contact surface has the form of a polygon. Preferably, this polygonal shape is a triangular, square, trapezoidal, polygonal, quadrangular, rectangular, polygonal, circular, elliptical, annular, arcuate form, or any combination thereof.

In embodiments of a component holder, preferably one or more of the temperature zones each has the form of a polygon. Preferably, this polygonal shape is a triangular, square, trapezoidal, polygonal, quadrilateral, rectangular, polygonal, circular, elliptical, linear, annular, arcuate form, or any combination thereof.

In embodiments of a component holder, in the case of multiple temperature zones, a first temperature zone is arranged in a central area of the component contact surface, a second temperature zone is arranged adjacent and peripheral to a first edge of the first temperature zone, a first PTC thermistor heating element of a third temperature zone is arranged adjacent and peripheral to a second edge of the first temperature zone, a fourth temperature zone arranged adjacent and peripheral to a third edge of the first temperature zone, and a second PTC thermistor heating element of the third temperature zone arranged adjacent and peripheral to a fourth edge of the first temperature zone, wherein the first temperature zone comprises multiple PTC thermistor heating elements connected in parallel.

In embodiments of a component holder, a fifth temperature zone is disposed adjacent and peripheral to a first edge of the first PTC thermistor heating element of the third temperature zone, and a sixth temperature zone is disposed adjacent and peripheral to a first edge of the second heating element of the third temperature zone.

In embodiments of a component holder, the first temperature zone has a square form and the second temperature zone, the first PTC thermistor heating element of the third temperature zone, the fourth temperature zone and the second PTC thermistor heating element of the third temperature zone have a trapezoidal form.

In the case of an embodiment of a component holder, a first PTC thermistor heating element of a first temperature zone is arranged in an inner central area of the component contact surface, a second PTC thermistor heating element of the first temperature zone is arranged adjacent and peripheral to a first edge of the first PTC thermistor heating element of the first temperature zone,

a third PTC thermistor heating element of the first temperature zone is arranged adjacent and peripheral to a second edge of the first PTC thermistor heating element of the first temperature zone, a fourth PTC thermistor heating element of the first temperature zone is arranged adjacent and peripheral to a third edge of the first PTC thermistor heating element of the first temperature zone, a fifth heating element of the first temperature zone is arranged adjacent to and peripheral to a fourth edge of the first PTC thermistor heating element of the first temperature zone, wherein the first temperature zone comprises multiple PTC thermistor heating elements connected in parallel.

In embodiments of a component holder, the first PTC thermistor heating element of the first temperature zone has a square form, wherein the second PTC thermistor heating element of the first temperature zone, the third PTC thermistor heating element of the first temperature zone, the third PTC thermistor heating element of the first temperature zone, the fourth PTC thermistor heating element of the first temperature zone and the fifth PTC thermistor heating element of the first temperature zone each have the form of a polygon. Preferably, as already described, this shape of the polygon is a triangular, square, trapezoidal, polygonal, quadrilateral, rectangular, polygonal, circular, elliptical, linear, annular, arcuate form or any combination thereof.

In embodiments of a component holder, a first PTC thermistor heating element of a second temperature zone is disposed adjacent and peripheral to a first edge of the second PTC thermistor heating element of the first temperature zone, a second PTC thermistor heating element of the second temperature zone is disposed adjacent and peripheral to a first edge of the third PTC thermistor heating element of the first temperature zone, and a third PTC thermistor heating element of the second temperature zone is disposed adjacent and peripheral to a first edge of the fifth PTC thermistor heating element of the first temperature zone, a third PTC thermistor heating element of the second temperature zone is arranged adjacent to and peripheral to a first edge of the fifth PTC thermistor heating element of the first temperature zone, and a fourth PTC thermistor heating element of the second temperature zone is arranged adjacent to and peripheral to a first edge of the fourth PTC thermistor heating element of the first temperature zone, wherein the second temperature zone comprises multiple PTC thermistor heating elements connected in parallel.

In embodiments of a component holder, a first PTC thermistor heating element of a third temperature zone is arranged adjacent to and peripheral to a first edge of the second PTC thermistor heating element of the second temperature zone, and a second PTC thermistor heating element of the third temperature zone is arranged adjacent to and peripheral to a first edge of the first PTC thermistor heating element of the third temperature zone, wherein the third temperature zone comprises multiple PTC thermistor heating elements connected in parallel.

In embodiments of a component holder, a first PTC thermistor heating element of a fourth temperature zone is arranged adjacent to and peripherally with respect to a first edge of the first PTC thermistor heating element of the second temperature zone, and a second PTC thermistor heating element of the fourth temperature zone is disposed adjacent to and peripheral to a first edge of the first PTC thermistor heating element of the fourth temperature zone, wherein the fourth temperature zone comprises multiple PTC thermistor heating elements connected in parallel.

In embodiments of a component holder, a first PTC thermistor heating element of a fifth temperature zone is arranged adjacent and peripheral to a first edge of the third PTC thermistor heating element of the second temperature zone, and a second PTC thermistor heating element of the fifth temperature zone is arranged adjacent and peripheral to a first edge of the first PTC thermistor heating element of the fifth temperature zone, wherein the fifth temperature zone comprises multiple PTC thermistor heating elements connected in parallel.

In embodiments of a component holder, a first PTC thermistor heating element of a sixth temperature zone is arranged adjacent to and peripherally with respect to a first edge of the fourth PTC thermistor heating element of the second temperature zone, and a second PTC thermistor heating element of the sixth temperature zone is disposed adjacent and peripheral to a first edge of the first PTC thermistor heating element of the sixth temperature zone, wherein the sixth temperature zone comprises multiple PTC thermistor heating elements connected in parallel.

In embodiments of a component holder, the component holder and/or its elements, preferably the support and/or, more preferably, the temperature-control apparatus and/or the component holding tool, also comprises one or more temperature sensors.

The temperature sensor can also be arranged as a layer in the temperature-control apparatus and cover a similar area to the heating elements, preferably PTC thermistor heating elements. The influence of the integration of electrical heating elements and the temperature sensor on the temperature homogeneity can be relatively low.

In embodiments of a component holder, a combination, preferably by parallel circuits, of heating elements for temperature zones, which act both in the plane and in the spatial volume, in particular in the case of a resulting composite layer of a temperature-control apparatus, depending on the requirements of the process-related temperature profile, has proven to be particularly advantageous for temperature-control in order to thermally shield one or more areas of the component contact surface of the component holding tool from the support during the processing of the component.

Embodiments of a component holder are arrangeable on a bond head so that it can pick up and hold any type of component, such as a semiconductor wafer, a semiconductor package, a chip, a flip chip, an integrated circuit, or an optical element, an electronic element, an electro-optical element or a combination thereof.

Embodiments of a component holder are locatable at a bonding station of a bonder in such a way that it can pick up and hold any type of component, such as a semiconductor wafer, a semiconductor package, a chip, a flip chip, an integrated circuit, or an optical element, an electronic element, an electro-optical element, a substrate, a wafer or a combination thereof.

The above-described arrangements of heating elements and/or PTC thermistor heating elements have each been described in dependence on the type of component, wherein the geometrical dimensions specify the number and the geometrically occupied area of the heating and/or PTC thermistor heating elements, and the technical effect of temperature-control during the processing of the component by thermally shielding the component from the support of the component holder results directly from this in each case.

In another aspect of the invention, a method of using a component holder according to any of the embodiments described above for controlling temperature-control of one or more areas of the component contact surface of the component holding tool, comprising controlling a relative temperature difference between one or more temperature zones and/or between one or more PTC thermistor heating elements of a temperature zone during a process step in which the component holder is used.

In preferred methods, the method of using a component holder comprising controlling a relative temperature difference between one or more temperature zones and/or between one or more PTC thermistor heating elements of a temperature zone to achieve a homogeneous distribution of the temperature of the component contact surface.

The embodiments EA1 to EA12 described below are not only suitable for use in combination with the supporting of components, but also in combination with the fixing of any components during the processing, in combination with other and/or further processes and in combination with other and/or further processing machines. These embodiments are:
EA1: A temperature-control apparatus comprising two or more heating elements, wherein each heating element is configured and arranged to increase a temperature of an adjacent area when the electron flow through a heating element of an electric current or voltage attachable to the heating elements or a voltage increases; wherein at least two of the two or more heating elements are connected in parallel; and wherein each heating element is configured and arranged such that the electrical resistance of each increases nonlinearly as the temperature of the adjacent area increases.
EA2: A temperature-control apparatus according to EA1, wherein each parallel-connected heating element comprises one or more PTC thermistors.
EA3: A temperature-control apparatus according to EA1 or EA2, wherein the increase in electron flow is accomplished by increasing the electrical voltage while keeping the electrical current constant, or by increasing the electrical current while keeping the electrical voltage constant.
EA4. A temperature-control apparatus according to EA1, according to EA2 or according to EA3, wherein each heating element comprises one or more electrically-conductive thin layers manufactured using thin-film deposition technology.
EA5. A component holder comprising a component contact surface and a temperature-control apparatus according to EA1, according to EA2, according to EA3 or according to EA4, wherein the temperature-control apparatus is configured and arranged such that, in operation, it increases the temperature of one or more areas of the component contact surface.
EA6: A component holder according to EA5, wherein the component contact surface has a low electrical conductivity, preferably has an electrically insulating effect, in one or more areas in the proximity of one or more heating elements.
EA7: A component holder according to EA5 or EA6, wherein in use the temperature of the component contact surface is, preferably homogeneously distributed over the component contact surface, can be increased.
EA8: An arrangement of mutually symmetrical heating elements, wherein the symmetries comprise concentrically-arranged zones comprising parallel zones with the same distance to the centre, wherein temperature-control layers with non-quadratic surfaces are designed with the edge areas as separate zones.
EA9: A temperature zone arrangement with a preferrably rectangular design for rectangular components, or also square or circular embodiments for thermally-shielding square or circular components.
Ea10: A temperature-control apparatus that can be arranged and/or attached to a carrier plate.
EA11: A carrier plate that is interchangeably connected to a component holder.
EA1: An interface for conducting or passing process media and/or electrical signals between a temperature-control apparatus and a component holder.
EA13: A controllable pass-through for process media in a temperature-control apparatus.

In addition, the following embodiments EA-P1 to EA-P23 have shown to be particularly suitable in practice:
EA-P1. Component holder (1) for the processing of a component, wherein the component holder (1) comprises as elements: a support (100), a component holding tool (300) with a component contact surface (350) and a temperature-control apparatus (200), wherein the temperature-control apparatus (200) is arranged on the support (100) such that, relative to the support (100), one or more areas of the component contact surface (350) of the component holding tool (300) are temperature-controllable relative to a predetermined process temperature for the processing of the component by means of a relatively positive or negative temperature, so that for the processing of the component, one or more areas of the component contact surface (350) of the component holding tool (300) is thermally shielded from the support (100).
EA-P2. Component holder (1) according to EA-P1, wherein the support (100) and the temperature-control apparatus (200) each have at least one media line (130, 131, 132, 133, 134, 135, 136, 137, 138, 139, 140, 141), each being arranged so that the support (100) is connected to the temperature-control apparatus (200) and the temperature-control apparatus (200) is connected with the component holding tool (300) force-fitting and/or form-fitting to each another, so that at least a portion of the relatively positive or negative temperature for temperature-controlling can be supplied to or drained off by means of at least one medium, preferrably for the processing of the component.
EA-P3. Component holder (1) according to EA-P1 or EA-P2, wherein the temperature-control apparatus (200) comprises one or more temperature zones (301, 302, 303, 304, 305, 306) that provide relatively positive temperature for one or more areas of the component contact surface (350).
EA-P4. Component holder (1) according to EA-P3, wherein each temperature zone (301, 302, 303, 304, 305, 306) has one or more electric heating elements (301a, 301b, 302, 302b, 303a, 303b, 304a, 304b, 305a, 305b, 306a, 306b).
EA-P5. Component holder (1) according to EA-P3, wherein one or more of the temperature zones (301, 302, 303, 304, 305, 306) has two or more PTC thermistor heating elements (301 a, 301b, 302b, 303a, 303b, 304a, 304b, 305a, 305b, 306a, 306b), which are electrically connected in parallel.
EA-P6. Component holder (1) according to EA-P4 or EA-P5, wherein each of one or more temperature zones (301, 302, 303, 304, 305, 306) is arranged to be electrically connected to one of n electrical power supplies and each of the electrical energy supplies is arranged to provide a predetermined and/or controlled supply of electrical energy to one of the temperature zones (301, 302, 303, 304, 305, 306).
EA-P7. Component holder (1) according to one of the embodiments EA-P3 to EA-P6, wherein at least one of the n temperature zones (301) is arranged in an inner central area of the component contact surface (350); and wherein at least one or more further temperature zones (302, 303, 304, 305, 306) are arranged in one or more outer areas of the component contact surface (350) peripheral to the inner central area.
EA-P8. Component holder (1) according to EA-P4 or EA-P5, wherein one or more heating elements (301a, 301b, 302, 302b, 303a, 303b, 304a, 304b, 305a, 305b, 306a, 306b) or one or more PTC thermistor heating elements (301a, 301b, 302, 302b, 303a, 303b, 304a, 304b, 305a, 305b, 306a, 306b) are applied as a thin film.
EA-P9. Component holder (1) according to any of the preceding embodiments, wherein the component contact surfaces (350) comprise a triangular, square, trapezoidal, polygonal, quadrilateral, rectangular, polygonal, circular, elliptical, annular, arcuate form, or any combination thereof.
EA-P10. Component holder (1) according to one of the embodiments EA-P3 to EA-P9, wherein one or more of the temperature zones (301, 302, 303, 304, 305, 306) has a triangular, square, trapezoidal, polygonal, quadrilateral, rectangular, polyangular, circular, elliptical, linear, annular, arc form, or any combination thereof.
EA-P11. Component holder (1) according to one of the embodiments EA-P3 to EA-P9, wherein in the case of multiple temperature zones, a first temperature zone (301) is arranged in a central area of the component contact surface (350), a second temperature zone (302) is arranged adjacent and peripheral to a first edge of the first temperature zone (301), a first PTC thermistor heating element (303a) of a third temperature zone (303) is arranged adjacent and peripheral to a second edge of the first temperature zone (301); a fourth temperature zone (304) is arranged adjacent and peripheral to a third edge of the first temperature zone (301); and a second PTC thermistor heating element (303 b) of the third temperature zone (303) is arranged adjacent and peripheral to a fourth edge of the first temperature zone (301); wherein the first temperature zone (301) comprises multiple PTC thermistor heating elements (301a, 301b, 301c, 301d, 301e) connected in parallel.
EA-P12. Component holder (1) according to embodiment EA-P11, wherein a fifth temperature zone (305) is arranged adjacent and peripherally to a first edge of the first PTC thermistor heating element (303a) of the third temperature zone (303), and a sixth temperature zone (306) is arranged adjacent and peripheral to a first edge of the second heating element (303b) of the third temperature zone (303).
EA-P13. Component holder (1) according to embodiment EA-P11 or embodiment EA-P12, wherein the first temperature zone (301) comprises a square form and wherein the second temperature zone (302), the first PTC thermistor heating element (303a) of the third temperature zone (303), the fourth temperature zone (304) and the second PTC thermistor heating element (303b) of the third temperature zone (303) comprising a trapezoidal form.
EA-P14. Component holder (1) according to one of the first embodiments, wherein a first PTC thermistor heating element (301a) of a first temperature zone (301) is arranged in an inner central area of the component contact surface (350), a second PTC thermistor heating element (301b) of the first-temperature-zone (301) is arranged adjacent and peripheral to a first edge of the first PTC thermistor heating element (301a) of the first temperature zone (301), a third PTC thermistor heating element (301c) of the first temperature zone (301) is arranged adjacent to and peripherally to a second edge of the first PTC thermistor heating element (301a) of the first temperature zone (301), a fourth PTC thermistor heating element (301d) of the first temperature zone (301) is arranged adjacent to and peripherally to a third edge of the first PTC thermistor heating element (301a) of the first temperature zone (301), a fifth heating element (301e) of the first temperature zone (301) is arranged adjacent and peripheral to a fourth edge of the first PTC thermistor heating element (301a) of the first temperature zone (301); wherein the first temperature zone (301) comprises multiple PTC thermistor heating elements (301a, 301b, 301c, 301d, 301e) connected in parallel.
EA-P15. Component holder (1) according to embodiment EA-P14, wherein the first PTC thermistor heating element (301a) of the first temperature zone (301) comprises a square or rectangular form; and wherein the second PTC thermistor heating element (301b) of the first temperature zone (301), the third PTC thermistor heating element (301 c) of the first temperature zone (301), the third PTC thermistor heating element (301c) of the first temperature zone (301), the fourth PTC thermistor heating element (301d) of the first temperature zone (301) and the fifth PTC thermistor heating element (301d) of the first temperature zone (301) comprising a polygonal form.
EA-P16. Component holder (1) according to embodiment EA-P14 or embodiment EA-P15, wherein a first PTC thermistor heating element (302a) of a second temperature zone (302) is arranged adjacent to and peripherally to a first edge of the second PTC thermistor heating element (301b) of the first temperature zone (301), a second PTC thermistor heating element (302b) of the second temperature zone (302) is arranged adjacent to and peripherally to a first edge of the third PTC thermistor heating element (301c) of the first temperature zone (301), a third PTC thermistor heating element (302c) of the second temperature zone (302) is arranged adjacent to and peripherally to a first edge of the fifth PTC thermistor heating element (301e) of the first temperature zone (301), and a fourth PTC thermistor heating element (302d) of the second temperature zone (302) is arranged adjacent to and peripherally to a first edge of the fourth PTC thermistor heating element (301d) of the first temperature zone (301); wherein said second temperature zone (302) is comprised of multiple PTC thermistor heating elements (302a, 302b, 302c, 302d) connected in parallel.
EA-P17. Component holder (1) according to embodiment EA-P10, wherein a first PTC thermistor heating element (303a) of a third temperature zone (303) is arranged adjacent to and peripherally to a first edge of the second PTC thermistor heating element (302b) of the second temperature zone (302), and a second PTC thermistor heating element (303b) of the third temperature zone (303) is arranged adjacent and peripheral to a first edge of the first PTC thermistor heating element (303a) of the third temperature zone (303); wherein the third temperature zone (303) comprises multiple PTC thermistor heating elements (303a, 303b) connected in parallel.
EA-P18. Component holder (1) according to embodiment EA-P10 or embodiment EA-P11, wherein a first PTC thermistor heating element (304a) of a fourth temperature zone (304) is arranged adjacent to and peripherally to a first edge of the first PTC thermistor heating element (302a) of the second temperature zone (302), and a second PTC thermistor heating element (304b) of the fourth temperature zone (304) is arranged adjacent to and peripheral to a first edge of the first PTC thermistor heating element (304a) of the fourth temperature zone (304); wherein the fourth temperature zone (304) comprises multiple PTC thermistor heating elements (304a, 304b) connected in parallel.
EA-P19. Component holder (1) according to embodiment EA-P10 to EA-P12, wherein a first PTC thermistor heating element (305a) of a fifth temperature zone (305) is arranged adjacent to and peripherally to a first edge of the third PTC thermistor heating element (302c) of the second temperature zone (302), and a second PTC thermistor heating element (305b) of the fifth temperature zone (305) is arranged adjacent and peripheral to a first edge of the first PTC thermistor heating element (305a) of the fifth temperature zone (305); wherein the fifth temperature zone (305) is comprised of multiple PTC thermistor heating elements (305a, 305b) connected in parallel.
EA-P20. Component holder (1) according to embodiment EA-P10 to EA-P13, wherein a first PTC thermistor heating element (306a) of a sixth temperature zone (306) is arranged adjacent to and peripherally to a first edge of the fourth PTC thermistor heating element (302d) of the second temperature zone (302), and a second PTC thermistor heating element (306b) of the sixth temperature zone (306) is arranged adjacent and peripheral to a first edge of the first PTC thermistor heating element (306a) of the sixth temperature zone (306); wherein the sixth temperature zone (306) is comprised of multiple PTC thermistor heating elements (306a, 306b) connected in parallel.
EA-P21. Component holder (1) according to any one of the preceding embodiments, wherein the component holder (1) further comprises one or more temperature sensors (400).
EA-P22. Method for using a component holder (1) according to any one of embodiments EA-P1 to EA-P21 for controlling temperature of one or more areas of the component contact surface (350), wherein the method comprises controlling and/or adjusting a relative temperature difference between one or more temperature zones and/or between one or more PTC thermistor heating elements of a temperature zone during a process step.
EA-P23. Method for using a component holder (1) according to embodiment EA-P22, the method comprising controlling a relative temperature difference between one or more temperature zones and/or between one or more PTC thermistor heating elements of a temperature zone to achieve a homogeneous distribution of the temperature of the component contact surface (350).

With all the embodiments of a component holder, a constant process temperature with a homogeneous temperature distribution or with a constant temperature profile over time is ensured in the immediate proximity of the component during operation and it's processing.

### BRIEF DESCRIPTION OF THE DRAWINGS

Further advantages and characteristics of the invention will be apparent from the following figures, namely:

FIG. 1 shows a perspective view of a component holder comprising a support, a component holding tool and a temperature-control apparatus;

FIG. 2 shows a top view of a component holder with a support, a component holding tool and a temperature-control apparatus;

FIG. 3 shows a side view of a component holder with a support, a component holding tool and a temperature-control apparatus;

FIG. 4 shows a sectional view of a component holder with a component holding tool and a temperature-control apparatus with pass-throughs for process media;

FIG. 5 shows the top side of a temperature-control apparatus for a component holder;

FIG. 6 shows the underside of a temperature-control apparatus for a component holder;

FIG. 7a shows an embodiment of an arrangement of heating elements of a temperature-control layer for a temperature-control apparatus;

FIG. 7b shows an embodiment of a temperature zoning of the arrangement of heating elements from FIG. 7a;

FIG. 8 shows an embodiment of a further temperature-control layer for a temperature-control apparatus with an arrangement of heating elements;

FIG. 9 shows an embodiment of a temperature-control apparatus with an arrangement of heating elements to form a square temperature zone;

FIG. 10 shows an embodiment of a further temperature-control layer for a temperature-control apparatus with an arrangement of the heating elements and their temperature zones;

FIG. 11 shows an embodiment of a temperature-control apparatus;

FIG. 12 shows a side view of a component holder with a support, a component holding tool and the temperature-control apparatus from FIG. 11.

### DETAILED DESCRIPTION OF DRAWINGS

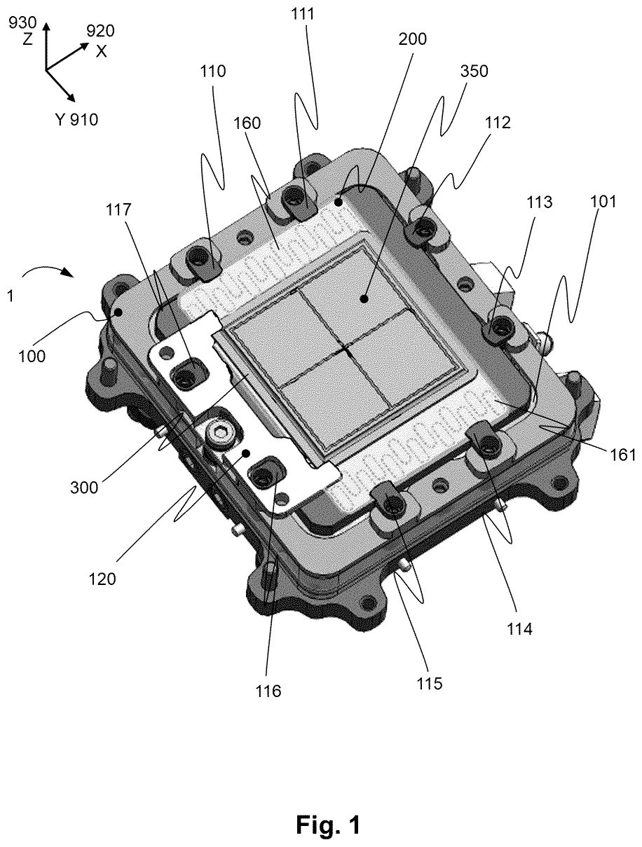

FIG. 1 shows a perspective view of a component holder 1 comprising a support 100, a temperature-control apparatus 200 and a component holding tool 300 having a component contact surface 350 for receiving and holding an non-depicted component of any kind, such as a semiconductor wafer, semiconductor package, chip, flip chip, integrated circuit, substrate, optical element, electronic element, electro-optical element, or combination thereof.

The component contact surface 350 is suitable for a variety of forms for supporting components (not illustrated). The variety of forms comprises, for example, the form of a triangle, a square, a trapezoid, a polygon, a quadrilateral, a rectangle, a polygon, a circle, an ellipse, a ring, an arc, or any combination thereof.

A vacuum is usually used to hold a component (not shown) in place on the component contact surface 350 during operation, which is provided as a process medium on the surface by means of, not shown, openings in media lines 130, 131, 132, 133 and 134. Preferrably, the process medium can also be distributed via additionally recesses let into the surface of the component contact surface 350, which are preferrably formed as half-channels extending orthogonally to one another. The additionally half-channel shaped recesses increase the intake surface for a component, resulting in a higher suction pressure and thus also a higher heat gradient between the component contact surface 350 and the component contact surface and a component to be hold by vacuum on that is in contact with it.

The component holder 1 is suitable for use on a non-depicted bond head, a non-depicted bond site or an apparatus for the processing of components.

The component holder 1 can be used in any type of apparatus or process step in which an improved, preferrably temperature-compensated, temperature behaviour of the component holder is required to ensure a constant process temperature with homogeneous temperature distribution or with a temporally constant temperature profile in the immediate vicinity of the component in operation. In particular in the case of mechanically very stable, large-mass component holders, which have a high heat capacity and thermal inertia due to their mass. For example, in the case of TCB (thermo-compression bonding) with heated bonding inserts or heated chucks, as well as in the case of other assembly processes for semiconductor chips and the holding tools required for them.

The support 100 has a recess 101 into which the temperature-control apparatus 200 is inserted in a force-fitting and/or form-fitting manner. The temperature-control apparatus 200 has multiple electrical contacts 160, 161 arranged on two opposite sides, which are shown as dashed lines. The electrical contacts 160, 161 are arranged for electrical contact with and control of hidden temperature zones (not shown) with embedded electrical heating elements (not shown), preferrably also PTC thermistor heating elements, which are operated, particularly preferably, connected in parallel, and/or arranged for electrical contact with and reading of non-depicted temperature sensors. The multiple electrical contacts 160, 161 can be provided, for example, using contact spring pins to allow for quick replacement. The use of more than one contact spring pin per contact point makes it possible to avoid overloading the contact spring pins. The electrical contact can also be accomplished via a rigid contact, for example in the form of pins or surface contacts.

Also not visible are the openings 142 and 143 on the bottom surface 51, which also serve, in a larger number, to supply and/or drain at least one medium in order to supply to and/or drain from at least a portion of the relatively positive or negative temperature for temperature-control.

The support 100 has eight holder clips 110, 111, 112, 113, 114, 115, 116 and 117, arranged in opposing pairs, for fixing the temperature-control apparatus 200.

Furthermore, a holder 120 is shown, which is one of two holders 120, 121 arranged opposite each other during operation for fixing the component holding tool 300.

The component holder 350 is preferrably centred and aligned with the temperature-control apparatus 200. It may be advantageous to take into account the thermal expansion during fixing and to take into account a mechanical tolerance of the holders 120, 121 accordingly, as well as to use an additional fixing with a vacuum already provided to the component holder, also for the additionally supporting fixing of the component holding tool 300.

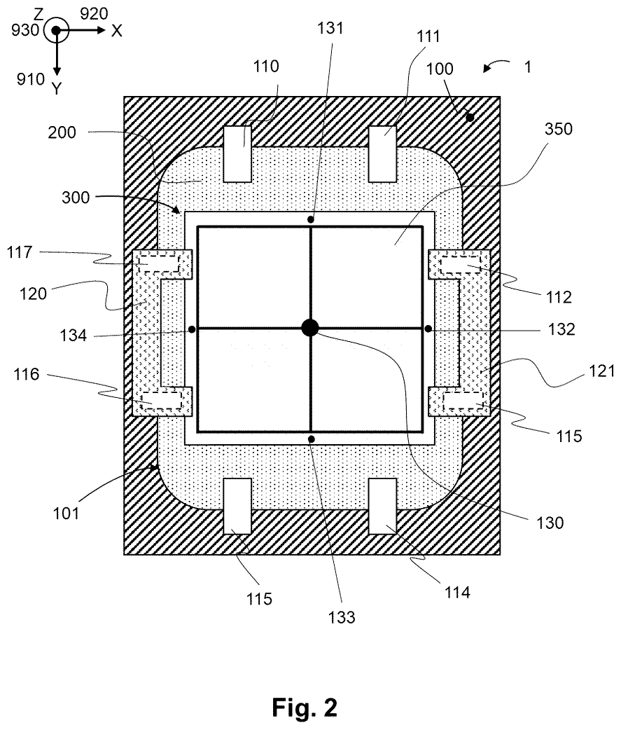

FIG. 2 is a top view of component holder 1 from FIG. 1 with additional details shown. The component holder 1 has the support 100, the component holding tool 300 and the temperature-control apparatus 200 in the recess 101, wherein the temperature-control apparatus 200 is fixed in the recess during operation by means of the two illustrated holders 120, 121 together with a vacuum fixing.

In particular, the 101 recess simplifies handling as a means of guidance in the case of a quick tool change, whereby embodiments without recesses 101 are also possible.

The two holders 120, 121 lie on the holder clips 112, 115 and 116, 117, which are indicated in pairs with dashed lines. The holder clips 110, 111 and 114, 115 are not covered.

Between the marked openings of the media line sections 130, 131, 132, 133 and 134, the u-shaped crossed recesses in the form of half-channels for holding a component resting on the component contact surface 350 during operation can be seen. As already explained, the vacuum-fixing surface for a component is increased by the additionally channel-shaped recesses, resulting in a higher suction pressure and thus also a higher heat gradient between the component contact surface 350 and the component contact surface and an applied and vacuum-fixed component.

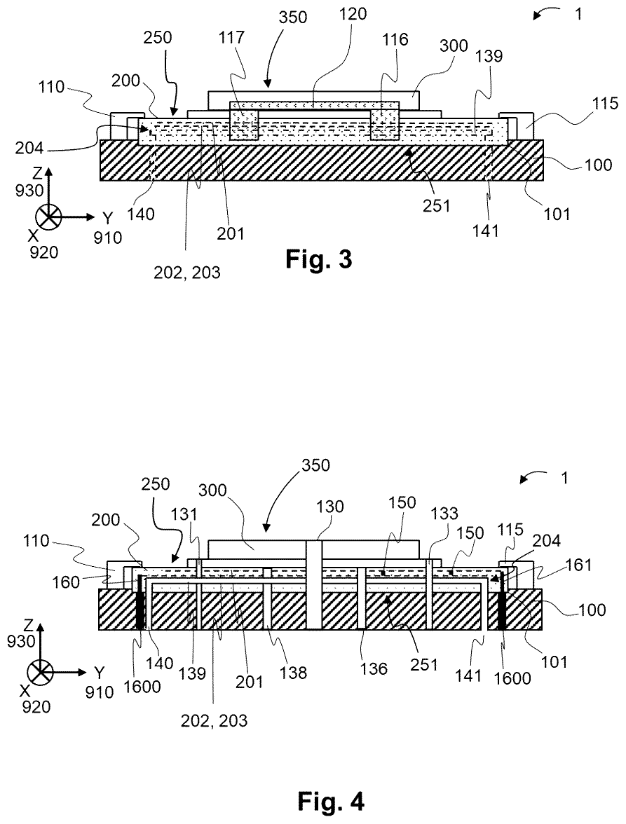

FIG. 3 shows the side view of the component holder 1 with the support 100, the component holding tool 300 and the temperature-control apparatus 200, as well as the holder 120 resting on the holder clips 117, 116. The side view shows the possible positions of embeddable temperature-control layers 201, 202, 203, 204 and the associated elements for electrical or fluidic operation for the temperature-control apparatus 200, some of which are indicated by dashed lines. Likewise, the media line section 140 and the media line section 141 are indicated in dashed lines, which extend through the force-fitting and/or form-fitting bottom surface 251 of the temperature-control apparatus 200 and the recess 101 of the support 100. Preferably, a vacuum is attachable through the two media lines 140 and 141 during operation to additionally support the temperature-control apparatus 200 in the recess 101.

Within the temperature-control apparatus 200, the media line section 140 and the media line section 141 serve, in addition to supporting the temperature-control apparatus 200 in the recess 101 during operation, to supply and/or drain at least a portion of the relatively positive or negative temperature via the media line section 139 for temperature-control by means of the temperature-control layer 204 via at least one medium, which is preferrably used for the processing of the component, such as compressed air, nitrogen, vacuum or another process gas. The supply and/or drain is accomplished by means of not-drawn openings 142 and 143 in the surface of the bottom surface 251, between which the media line section 139 extends.

For the sake of clarity, the side view from FIG. 3 is illustrated as a sectional view in FIG. 4.

FIG. 4 shows a sectional view of the component holder 1 with the component holding tool 300 and the temperature-control apparatus 200 held in the recess 101 of the support 100 by means of the holders 110, 115.

In use, the component holding tool 300 is additionally fixable by means of a vacuum on the top surface 250 of the temperature-control apparatus 200. The vacuum can therefore be applied using the media line sections 138 and 136 formed in use by the pass-throughs in the support 100 and the temperature-control apparatus 200.

The support 100 has the media line sections 140 and 141, the media line sections 131, 133 and the pass-throughs for process media in the form of the media line section 140, the media line section 139 embedded in the temperature-control apparatus 200 and the media line section 141. During operation, a vacuum can be applied by means of the media line sections 131, 133 and 130 to support a component on the component contact surface 350.

The media line section 139 embedded in the temperature-control layer 204 is meandering, as indicated, parallel to the temperature-control layers 201, 202, 203 and, preferrably as indicated, in the XY plane drawn around at least a portion of the media line sections 131, 130, 130. The media line section 139 serves the temperature-control layer 204 for the supply and/or drain of at least one of the available media, in order to supply and/or drain at least a portion of the relatively positive or negative temperature for temperature-control. In the case of particularly fast or short heating or cooling cycles, it has proven advantageous to embed multiple media line sections in the temperature-control layer 204, running preferrably parallel to one another, instead of a single media line section 139. Furthermore, it has proven advantageous to divide the media line sections at least partially into parallel, channel-shaped single channels, wherein their course and geometry is adapted to the available spatial volume and the required temperature profile. Practice has shown that a channel-shaped division of media line sections improves the static behaviour of a temperature-control apparatus in the case of an increase in the number of media line sections, so that an increased supply and/or draining of temperature is possible in the same area.

The temperature-control layers 201, 202 and 203 are interconnected by means of electrical through-hole connections 150 and can be electrically contacted by means of electrical contacts 160 and 161, for example by means of non-depicted spring contact pins in the recess 101 of the support 100.

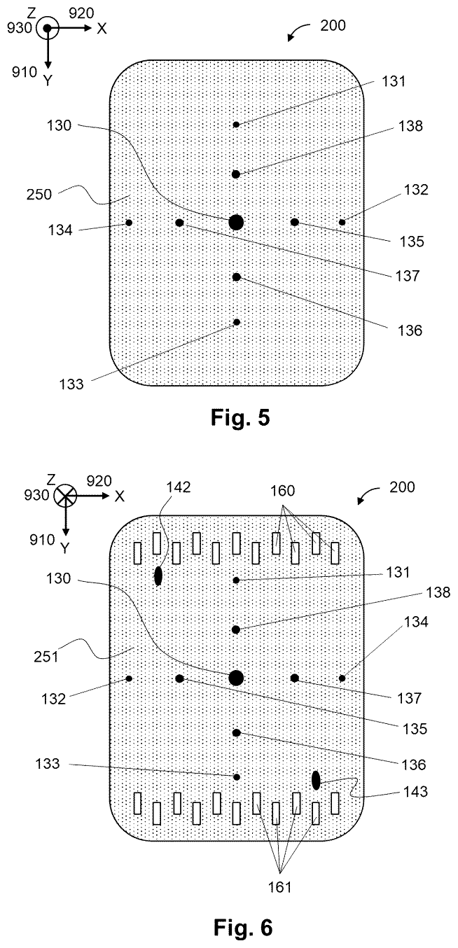

FIG. 5 shows the top surface 250 of a temperature-control apparatus 200 for a component holder 1 with the centrally arranged media line section 130 and the media line sections 131, 132, 133, 134, 135, 136, 137 and 138, each of which opens onto the upper side surface 250.

FIG. 6 shows the bottom surface 251 of a temperature-control apparatus 200 for a component holder 1 with the centrally arranged media line section 130. Around the centrally arranged media line section 130, the media line sections 131, 132, 133, 134, 135, 136, 137 and 138 are arranged in a cross shape. In addition, in this embodiment, both openings 142 and 143 of the bottom surface 251 are also visible. Between these two openings 142 and 143, the media line section 139 extends for the supply and/or drain of at least a portion of the relatively positive or negative temperature.

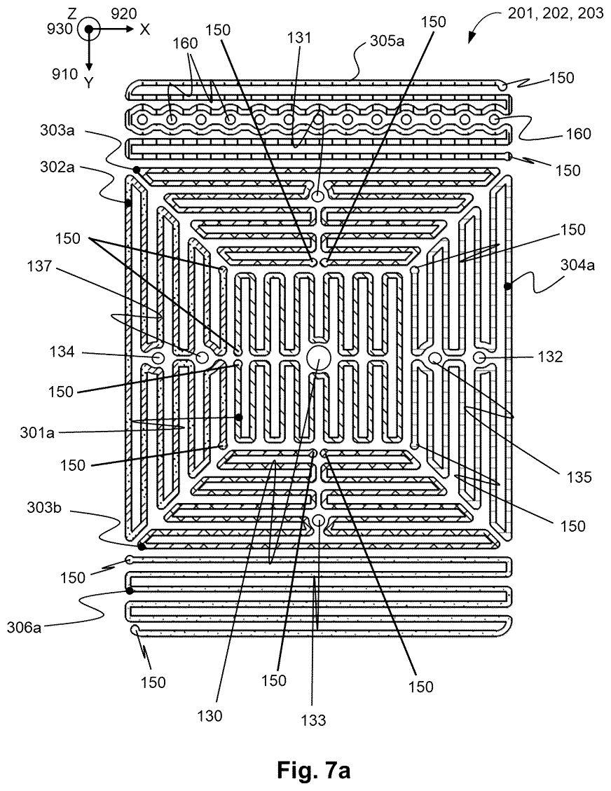

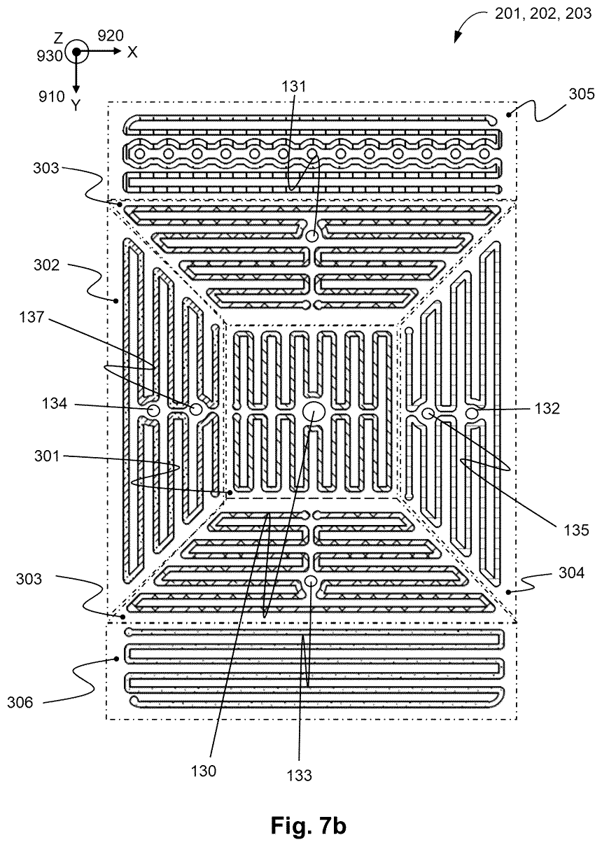

FIG. 7a and FIG. 7b show the same embodiment of an arrangement of heating elements 301a, 302a, 303a, 303b, 304a, 305a, 306a of a temperature-control layer 201, 202, 203 for a non-depicted rectangular temperature-control apparatus 200, wherein the reference signs and the temperature zones are distributed over the two FIGS. 7a and 7b in such a way that the temperature zones are only drawn in FIG. 7b for the sake of clarity. FIG. 7a shows the arrangement of heating elements 301a, 302a, 303a, 303b, 304a, 305a, 306a of a temperature temperature-control layer 201, 202, 203 for a non-depicted rectangular temperature-control apparatus 200, such as is suitable for components with a rectangular base surface. The heating elements 301a, 302a, 303a, 303b, 304a, 305a, 306a, embedded in the temperature-control apparatus 200, each have an electrical through-hole connection 150 at both ends for electrical contact, as well as the electrical contacts 160 that are fed through, of which only three have been indicated for the sake of clarity. In addition, in the case of this embodiment of a temperature-control layer 201, 202, 203, the media line sections 130, 131, 132, 133, 134, 135 and 137—indicated here with a circular cross-section—can be seen in the corresponding recesses in the meanders of the heating elements 301a, 302a, 303a, 303b, 304a and 305a. The specific design of the cross-section of the media line sections 130, 131, 132, 133, 134, 135 and 137 can also be arbitrary in the case of this embodiment, but preferrably with a channel-shaped division, and should not be limited by the schematic drawings used to keep the overview when interpreting the disclosure. In particular, embodiments of a temperature-control layer can also have further or fewer media line sections than schematically indicated in FIG. 7, depending on the requirements for the temperature zones.

In the case of this embodiment, the heating elements 301a, 302a, 303a, 303b, 304a, 305a, 306a are divided into the temperature zones 301, 302, 304, 305 and 306 as illustrated in FIG. 7b by an electrical circuit of the heating elements 301a, 302a, 304a, 305a and 306a, which is not shown. The two heating elements 303a, 303b are connected together in parallel and form a further temperature zone 303.

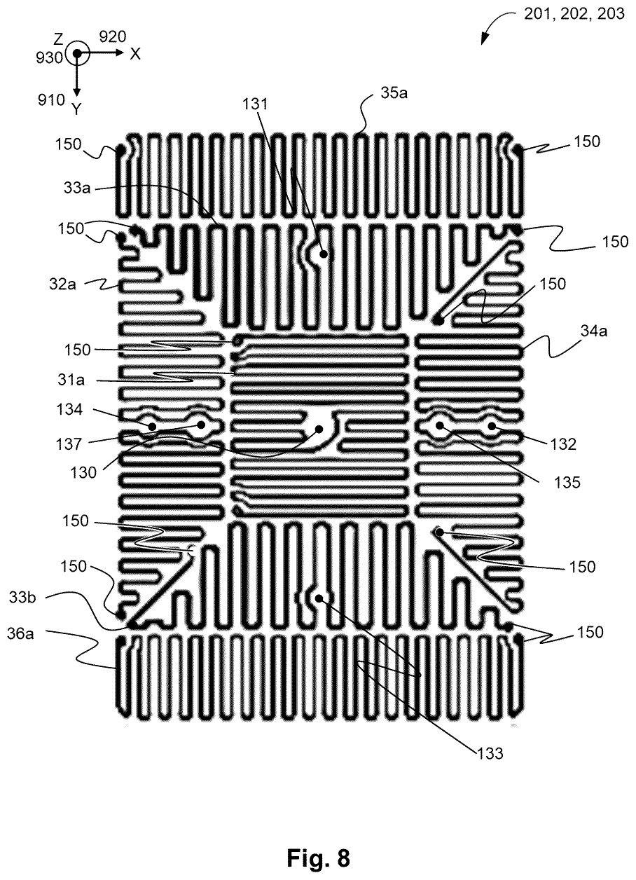

FIG. 8 shows an embodiment of a temperature-control layer 201, 202, 203 for a temperature-control apparatus 200 with an arrangement example of the heating elements for a component with a rectangular base surface, which is arrangeable together with a further temperature-control layer within a temperature-control apparatus 200. The arrangement of the heating elements 31a, 32a, 33a, 33b, 34a, 35a, 36a corresponds to the arrangement of the heating elements of the heating elements 301a, 302a, 303a, 303b, 304a, 305a, 306a illustrated in FIG. 7. Even if their respective meander geometry differs from each other, the respective electrical through-hole connections 150 are aligned with each other in the case of a superimposed arrangement of the two temperature-control layers, so that the heating elements of the two temperature-control layers of FIGS. 7 and 8 can be electrically interconnected within a temperature-control apparatus 200 to form temperature zones of the temperature-control apparatus 200 using electrical connecting lines not shown. In particular, the heating elements 301a, 302a, 303a, 303b, 304a, 305a, 306a of FIG. 7 can be interconnected in parallel with the heating elements 31a, 302a, 33a, 33b, 34a, 35a, 36a of FIG. 8 in such a way that the heating elements 301a and 31a form a first temperature zone 31 in the spatial volume of a resulting composite layer of a temperature-control apparatus 200. The heating elements 302a and 32a form a second temperature zone 32 in the spatial volume of a resulting composite layer of a temperature-control apparatus 200. The heating elements 304a and 34a, 305a and 35a as well as 306a and 36a also form the respective temperature zones 304, 305 and 306 in the spatial volume of a resulting composite layer of a temperature-control apparatus 200 in a corresponding parallel connection. The heating elements 303a and 303b as well as 33a and 33b, which are already connected in parallel with each other in the plane of the illustrated temperature-control layer 201, 202, 203, thus forming temperature zones 303 and 33 in the composite layer, each acting in the plane as well as in the spatial volume.

The electrical circuit of the heating elements is not shown for the sake of clarity. A combination of heating elements to form temperature zones, which act both in the plane and in the spatial volume, in particular in a resulting composite layer of a temperature-control apparatus, is particularly advantageous for temperature control, depending on the requirements of a process-related temperature profile, so that one or more areas of the component contact surface of the component holding tool are thermally shielded from the support for the processing of the component.

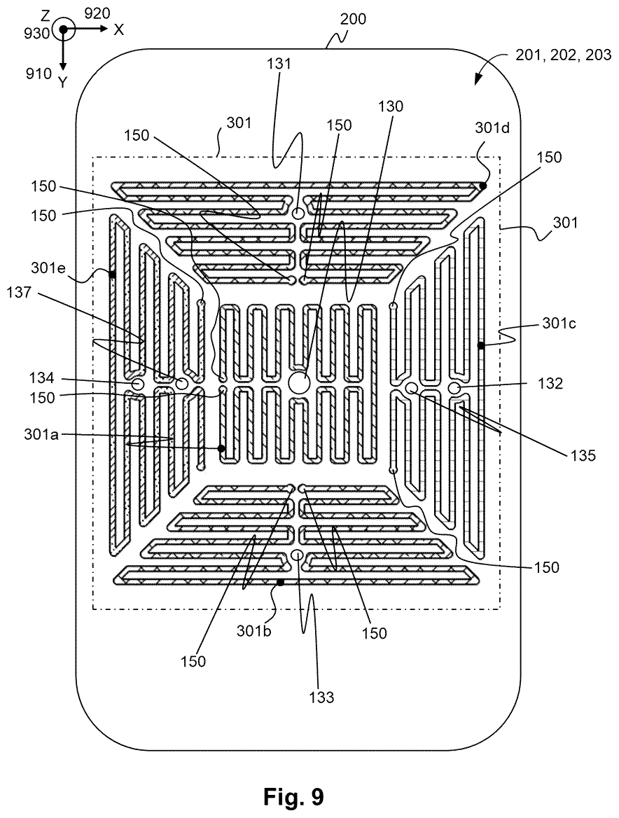

FIG. 9 shows an embodiment of a temperature-control layer 201, 202, 203 of a temperature-control apparatus 200. The temperature-control layer 201, 202, 203 has a temperature zone 301 in square form with a first heating element 301a in the centre and four further heating elements 301b, 301c, 301d and 301e arranged evenly around this heating element 301a. The temperature zone 301 is arranged as shown, preferably symmetrically, centred to the outer edges of the temperature-control layer 201, 202, 203. The electrical circuits of the heating elements are not shown for the sake of clarity. The heating elements are preferably all designed as PTC thermistor heating elements and the outer heating elements 301b, 301c, 301d and 301e can each be connected in pairs as adjacent or opposite pairs in parallel, depending on the requirements of the temperature profile.

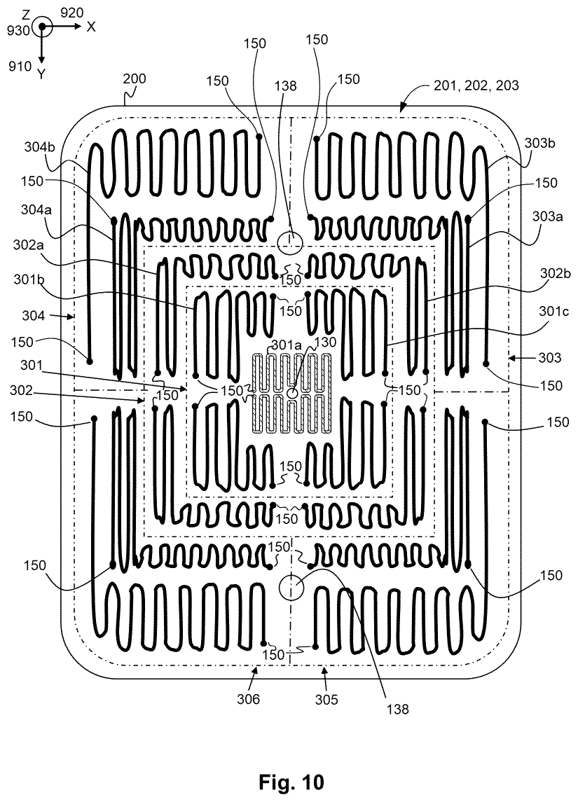

FIG. 10 shows an embodiment of a rectangular temperature-control layer 201, 202, 203 for a temperature-control apparatus 200 not shown with an advantageous arrangement of the temperature zones 301, 302, 303, 304, 305 and 306 for one or more components not shown with a square or rectangular base area. The temperature-control layer 201, 202, 203 has a first temperature zone 301 in a square form with a first heating element 301a in the centre and four further heating elements 301b, 301c, 301d and 301e arranged evenly around this heating element 301a. The temperature zone 301 is arranged, preferably symmetrically, centred to the outer edges of the temperature-control layer 201, 202, 203. The second heating element 301b of the temperature zone 301, the third heating element 301c of the temperature zone 301, the third heating element 301c of the temperature zone 301, the fourth heating element 301d of the temperature zone 301 and the fifth heating element 301d of the first temperature zone 301 each have the form of a polygon in order to be able to enclose the first heating element 301a uniformly arranged in the XY plane. In this embodiment, the form of a polygon is angular or L-shaped in each case. In addition, the first heating element 301a of the first temperature zone 301 has a recess in its meander geometry in the centre, through which the media line section 130 runs vertically in the image plane XY. The heating elements are preferably all arranged to be PTC thermistor heating elements. The first temperature zone 301 is surrounded by the concentrically arranged temperature zone 302. The temperature zone 302 also comprises 4 uniformly arranged polygons, each angular or L-shaped, which enclose the 5 heating elements of the first temperature zone in the XY plane, i.e. in a plane of a composite layer of a temperature-control apparatus 200 not shown.

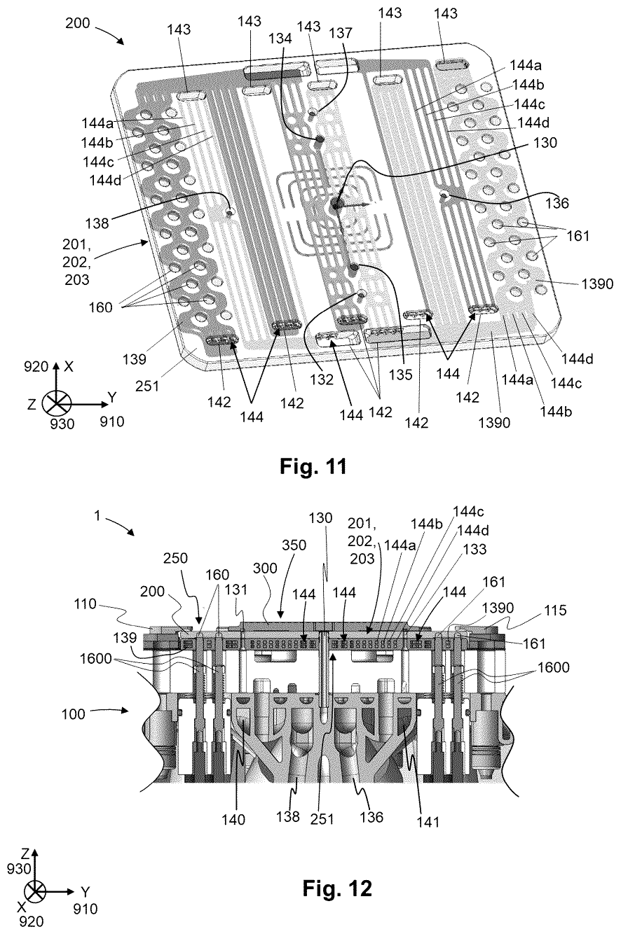

FIG. 11 shows an embodiment of a temperature-control apparatus 200 with a composite layer comprising the temperature-control layers 201, 202, 203 and 204, wherein only the temperature-control layer 204 is shown in the composite layer for the sake of clarity. The transparently-depicted perspective view of the bottom surfaces of the temperature-control apparatus 200 with view of the bottom surface 251 allows for a good understanding of the composite layer. The temperature-control layer 204 comprises the media line section 139 running in a meandering pattern in the composite layer and the media line section 1390 running in a meandering pattern in the composite layer. In this embodiment, the two media line sections are arranged mirror-inverted to each other in such a way that their meanders interlock in a comb-shaped manner. Furthermore, the two media line sections 139 and 1390 are each divided at least in sections or partially into channel-shaped single channels 144a, 144b, 144c, 144d running parallel to each other, wherein their course and geometry are adapted to the available volume of space and required temperature profile. On the bottom surface 251, the recessed openings 142 and 143 are clearly visible, which also serve in larger numbers to supply and/or drain at least one medium into and/or out of a media line section 139, 1390 in order to supply and/or drain at least a portion of the relatively positive or negative temperature for temperature control, and the channel-shaped division 144 can be easily recognised due to the perspective view in the respective openings 142 of the media line section 139. It has been shown in practice that a channel-shaped division 144 of media line sections generally improves the static behaviour of a temperature-control apparatus 200 when the number of media line sections is increased, so that an increased supply and/or draining of temperature is possible on the same area of the temperature-control layer 204. In addition, in this embodiment of a temperature-control layer 204, the media line sections 130, 132, 134, 136, 137 and 138 are partially recognisable in corresponding recesses in the media line sections 139 and 1390.

FIG. 12 shows a cross-sectional view of a component holder 1 with a partially-depicted support 100, which supports the temperature-control apparatus of FIG. 11 with the holder clips 110 and 115 and other non-depicted holder clips. The component holding tool 300 with the component contact surface 350 is placed on the top surface of the temperature-control apparatus 200. The contacts 160 and 161 of the temperature-control apparatus 200 for electrical contacting of the corresponding temperature-control layer 201, 202, 203 in the composite layer of the temperature-control apparatus 200 are electrically contacted by the contact spring pins 1600, thus establishing an electrical connection to the power supply and control unit of the temperature-control apparatus 200, which are not shown. Contact spring pins 1600 are embedded in the support 100 and the component holder 1. Furthermore, the support 100 and the component holder 1 have multiple media line sections 136, 138, 140, 141 for supplying and/or draining temperature to and/or from the temperature-control apparatus 200 with the aid of media, preferably liquid or gaseous process media, as energy carriers. Furthermore, the cross-sectional view results in the advantageous arrangement and embodiment of the channel-shaped division 144 of the two media line sections 139 and 1390 into single channels 144a, 144b, 144c, 144d running parallel to each other at least in sections or in part in the composite layer of the temperature-control apparatus 200. Furthermore, the force-fitting and/or form-fitting connection of the support 100 to the temperature-control apparatus 200 and a force-fitting and/or form-fitting connection of the temperature-control apparatus 200 to the component holding tool 300 shows media lines (without reference signs) formed from the media line sections 130, 130a, 131, 131a, 136, 138, 140 and 141. These formed media lines (without reference signs) also serve to supply and/or drain at least one medium into and/or out of a media line section, in order to supply and/or drain at least a portion of the relatively positive or negative temperature for temperature control.

What is claimed is:

1. A component holder for processing a component, wherein the component holder comprises: a support, a component holding tool with a component contact surface and a temperature-control apparatus, wherein the temperature-control apparatus is arranged on the support such that, relative to the support, one or more areas of the component contact surface of the component holding tool are temperature-controllable relative to a predefined process temperature for processing the component by means of relatively positive or negative temperature, so that for the processing of the component, one or more areas of the component contact surface of the component holding tool is thermally shielded from the support.

2. A component holder according to claim 1, wherein the support and the temperature-control apparatus each have at least one media line, with each media line arranged so that the support is connected to the temperature-control apparatus and the temperature-control apparatus is connected to the component holding tool both force-fitting and/or form-fitting, such that at least a portion of the relatively positive or negative temperature is suppliable or drainable for temperature-controlling via means of at least one medium for the processing of the component.

3. A component holder according to claim 1, wherein the temperature-control apparatus comprises one or more temperature zones which provide relatively positive temperature for the one or more areas of the component contact surface.

4. A component holder according to claim 2, wherein the temperature-control apparatus comprises one or more temperature zones which provide relatively positive temperature for the one or more areas of the component contact surface.

5. A component holder according to claim 3, wherein each temperature zone comprises one or more electric heating elements.

6. A component holder according to claim 3, wherein one or more of the temperature zones comprises two or more PTC thermistor heating elements which are electrically connected in parallel.

7. A component holder according to claim 4, wherein each of the one or more temperature zones is arranged to be electrically connected to one of a plurality of electrical power supplies, and each of the electrical energy supplies is arranged to provide a predetermined and/or controlled supply of electrical energy to one of the temperature zones.

8. A component holder according to claim 3, wherein at least one of the n temperature zones is arranged in an inner central area of the component contact surface; and wherein at least one further temperature zone is arranged in one or more outer areas of the component contact surface peripheral to the inner central area.

9. A component holder according to claim 5, wherein one or more heating elements or one or more PTC thermistor heating elements are deposited as a thin film.

10. A component holder according to claim 9, wherein the component contact surfaces comprise a triangular, square, trapezoidal, polygonal, quadrangular, rectangular, polygonal, circular, elliptical, annular, arcuate form, or any combination thereof.

11. A component holder according to claim 3, wherein one or more of the temperature zones comprise a triangular triangular, square, trapezoidal, polygonal, quadrilateral, rectangular, polyangular, circular, elliptical, linear, annular, arcuate form, or any combination thereof.

12. A component holder according to claim 3, wherein, in the case of multiple temperature zones, a first temperature zone is arranged in a central area of the component contact surface, a second temperature zone is arranged adjacent and peripherally to a first edge of the first temperature zone, a first PTC thermistor heating element of a third temperature zone is arranged adjacent to and peripherally to a second edge of the first temperature zone; a fourth temperature zone is arranged adjacent and peripheral to a third edge of the first temperature zone; and a second PTC thermistor heating element of the third temperature zone is arranged adjacent and peripheral to a fourth edge of the first temperature zone; wherein the first temperature zone comprises multiple parallel connected PTC thermistor heating elements.

13. A component holder according to claim 11, wherein a first PTC thermistor heating element of a third temperature zone is arranged adjacent to and peripherally to a first edge of the second PTC thermistor heating element of the second temperature zone, and a second PTC thermistor heating element of the third temperature zone is arranged adjacent and peripheral to a first edge of the first PTC thermistor heating element of the third temperature zone; wherein the third temperature zone comprises multiple PTC thermistor heating elements connected in parallel.

14. A component holder according to claim 13, the component holder furthermore comprising one or more temperature sensors.

15. A method for using a component holder, the component holder comprising a support, a component holding tool with a component contact surface and a temperature-control apparatus, wherein the temperature-control apparatus is arranged on the support such that, relative to the support, one or more areas of the component contact surface of the component holding tool are temperature-controllable relative to a predefined process temperature for processing the component by means of relatively positive or negative temperature, so that for the processing of the component, one or more areas of the component contact surface of the component holding tool is (are) thermally shielded from the support, the method comprising: controlling a relative temperature difference between at least two of the one or more areas of the component contact surface during a process step.

16. A method for using a component holder, the component holder comprising a support, a component holding tool with a component contact surface and a temperature-control apparatus, wherein the temperature-control apparatus is arranged on the support such that, relative to the support, one or more areas of the component contact surface of the component holding tool are temperature-controllable with a PTC thermistor heating element relative to a predefined process temperature for processing the component by means of relatively positive or negative temperature, so that for the processing of the component, one or more areas of the component contact surface of the component holding tool is (are) thermally shielded from the support, the method comprising: controlling a relative temperature difference between at least two of the one or more areas of the component contact surface and/or between one or more PTC thermistor heating elements corresponding to the two of the areas to achieve a homogeneous distribution of the temperature of the component contact surface during a process step.
